(19) United States
(12) Patent Application Publication
(10) Pub. No.: US 2009/0273892 A1
(43) Pub. Date: Nov. 5, 2009

(54) COUPLING STRUCTURE FOR MICROCOMPUTER CASES

(75) Inventor: TA-YANG CHENG, Taipei (TW)

Correspondence Address: SCHMEISER, OLSEN & WATTS, 22 CENTURY HILL DRIVE, SUITE 302, LATHAM, NY, 12110, US

(73) Assignee: KING YOUNG TECHNOLOGY CO., LTD., TAIPEI CITY (TW)

(21) Appl. No.: 12/113,485

(22) Filed: May 1, 2008

(51) Int. Cl. H05K 7/00; H05K 5/00; G06F 1/16

(52) U.S. Cl. 361/679.6; 361/728

(57) ABSTRACT

A coupling structure for microcomputer cases includes at least two microcomputer cases and at least two coupling units for coupling the two cases together. Each of the cases is provided along four longitudinal outer corners with a slide channel each. The coupling units each include a longitudinally extended body portion and two insertion ribs separately extended along and from two longitudinal sides of the body portion. The insertion ribs are configured corresponding to the slide channels on the cases to be slidably fitted in the slide channels on two adjoining sides of the two cases that are juxtaposed or stacked, so as to firmly couple the two cases together.

### FIELD OF THE INVENTION

The present invention relates to a coupling structure for microcomputer cases, and more particularly to a coupling structure for firmly coupling two or more juxtaposed or stacked microcomputer cases together using coupling units.

### BACKGROUND OF THE INVENTION

In the computer case of a personal computer, there are mounted various components, including motherboard, hard disc drive, floppy disc drive, CD-ROM drive, recorder, power supply, heat radiator, etc. The motherboard is electrically connected to other components via flat cables. Various factors, such as the large volume of the heat radiator, the improper arrangement of different components in the computer case, and the large space occupied by the flat cables, result in a huge volume of the computer case.

A microcomputer is developed to improve the large case of the personal computer. However, due to limited usable internal space, some components are omitted from the microcomputer case. As a result, the microcomputer loses certain functions and fails to satisfy some users. In order to overcome this problem, some users have tried to link the interfaces of two or more microcomputers to meet actual need in using the microcomputers.

However, the linked microcomputers are frequently arbitrarily positioned on a desk top to occupy additional room. While some users would position the linked microcomputers side by side or stack them on the desk, the microcomputers are not firmly held to each other. Consequently, after being used for a period of time, the linked microcomputers, either positioned side by side or stacked, are likely to displace from each other and become disorderly rested on the desk again.

### SUMMARY OF THE INVENTION

It is therefore a primary object of the present invention to provide a coupling structure for firmly coupling two or more horizontally juxtaposed or vertically stacked microcomputer cases together.

To achieve the above and other objects, the coupling structure for microcomputer cases according to the present invention includes at least two microcomputer cases and at least two coupling units for coupling the two cases together. Each of the cases is provided along four longitudinal outer corners with a slide channel each. The coupling units each include a longitudinally extended body portion and two insertion ribs separately extended along and from two lateral sides of the body portion. The insertion ribs are configured corresponding to the slide channels on the cases to be slidably fitted in the slide channels on two adjacent sides of two cases that have been closely juxtaposed or stacked, so as to firmly couple the two cases together.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is an exploded perspective view of a microcomputer case according to the present invention;

FIG. 2 is a perspective view of a coupling unit according to the present invention;

FIG. 3 is a perspective view showing the manner of horizontally coupling two microcomputer cases together using two pieces of the coupling units of the present invention;

FIG. 4 shows the two microcomputer cases of FIG. 3 in a horizontally coupled state;

FIG. 5 is an assembled sectional view of the two horizontally coupled microcomputer cases; and

FIG. 6 is an assembled sectional view showing two microcomputer cases are vertically coupled together using two pieces of the coupling units of the present invention.

### DETAILED DESCRIPTION OF THE PREFERRED EMBODIMENTS

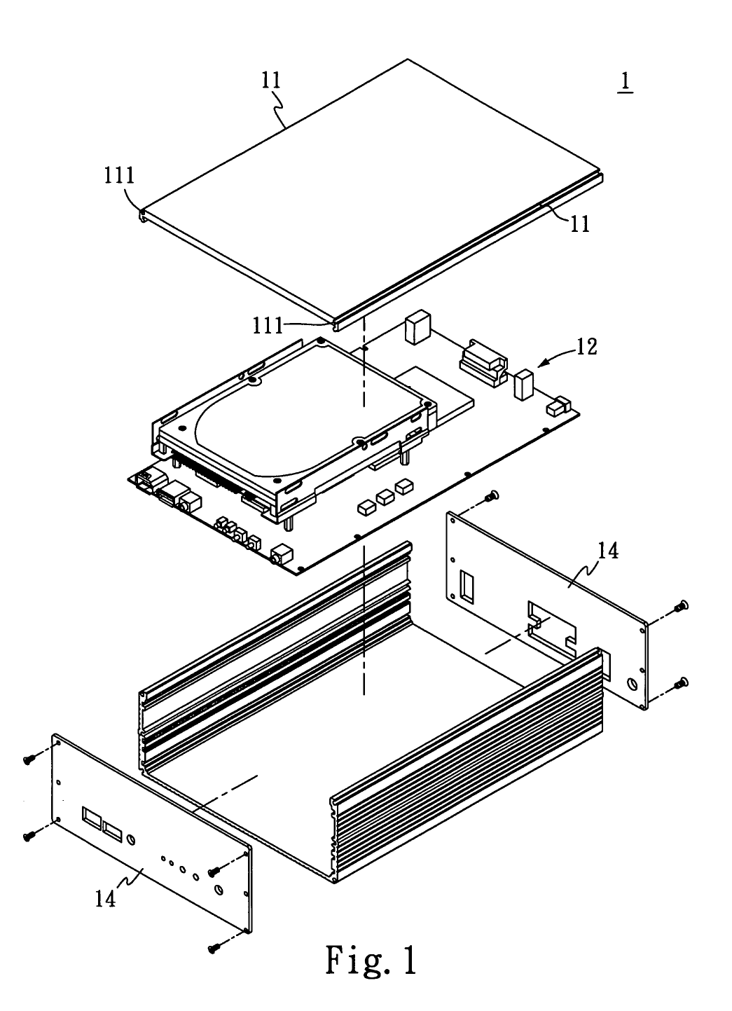

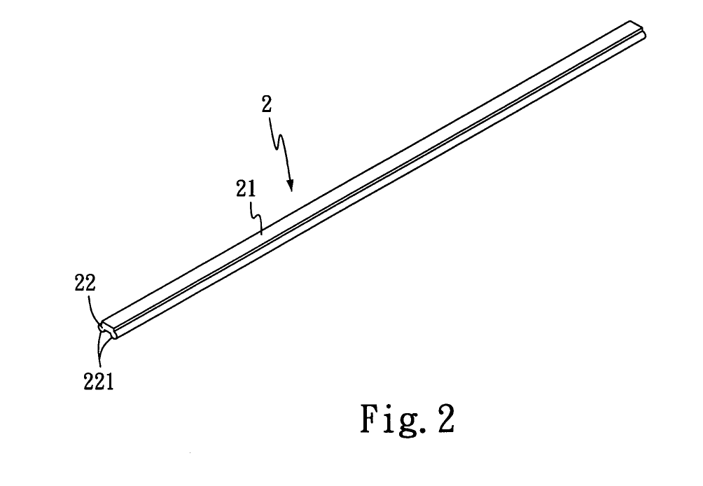

A coupling structure for microcomputer cases according to the present invention includes at least two microcomputer cases 1 and at least two coupling units 2 for coupling the two cases 1 together. FIGS. 1 and 2 are perspective views showing the microcomputer case 1 and the coupling unit 2, respectively.

Each of the cases 1 is provided along four longitudinal outer corners with a slide channel 11 each. The slide channels 11 each have a bottom formed into a concave-sectioned recess 111. A motherboard 12 is installed in the case 1, and two end panels 14 are separately fixed to front and rear open ends of the case 1.

Each of the coupling units 2 includes a longitudinally extended body portion 21 having a predetermined width, and two insertion ribs 22 separately extended along and from two longitudinal sides of the body portion 21. The insertion ribs 22 are configured corresponding to the slide channels 11 on the case 1, and each have a round-sectioned projection 221 formed along a free edge thereof for slidably fitted in the concave-sectioned recesses 111 of the slide channels 11.

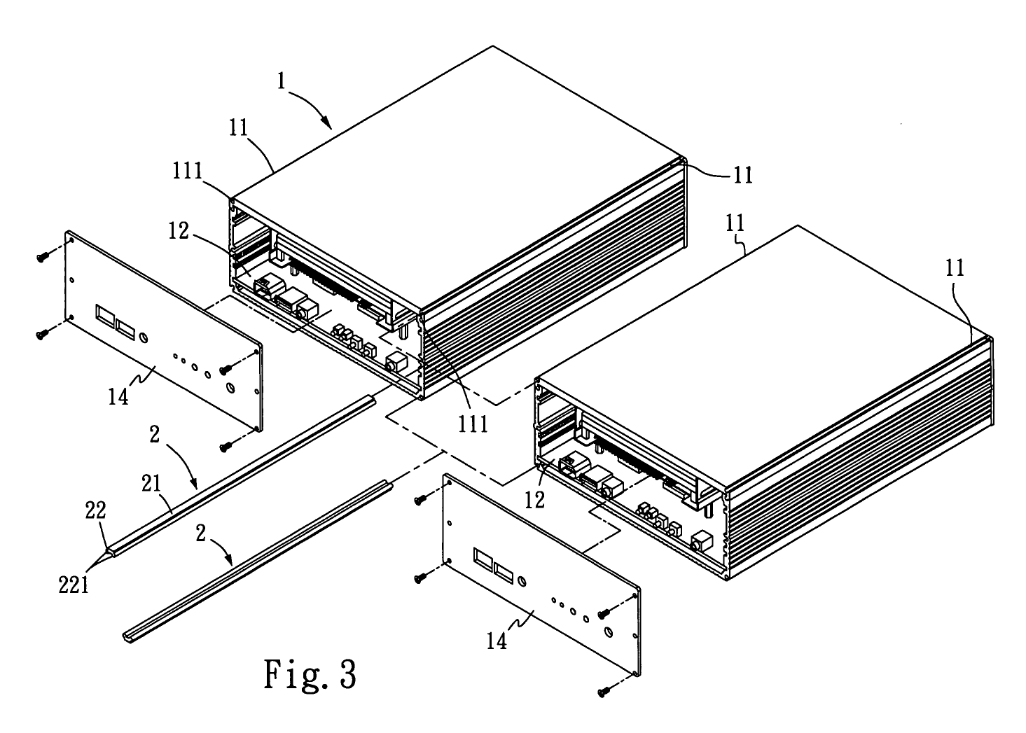

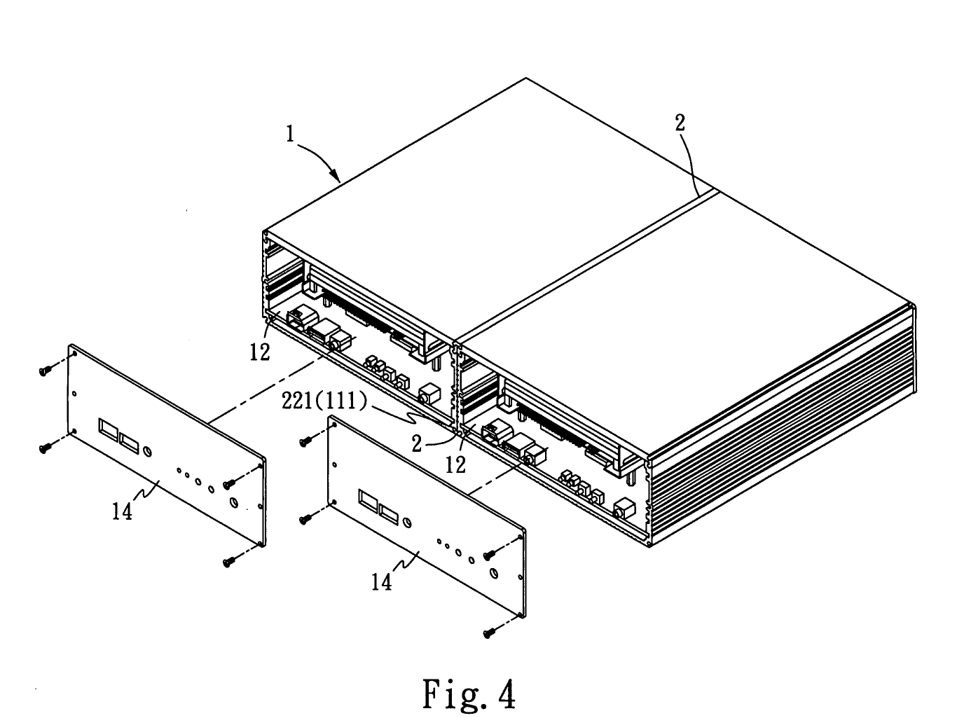

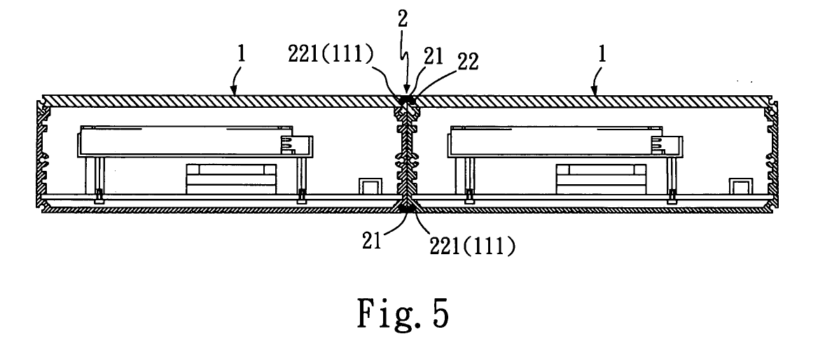

Please refer to FIGS. 3 to 5. Two cases 1 of the present invention may be horizontally coupled together by positioning them side by side with the slide channels 11 correspondingly located at two horizontally adjoining sides of the two cases 1 in close contact with one another. Then, engage one coupling unit 2 with each pair of two adjoining slide channels 11 with the round-sectioned projections 221 on the insertion ribs 22 of the coupling unit 2 slidably fitted in the concave-sectioned recesses 111 in the slide channels 11. In this manner, the two cases 1 are firmly horizontally coupled together.

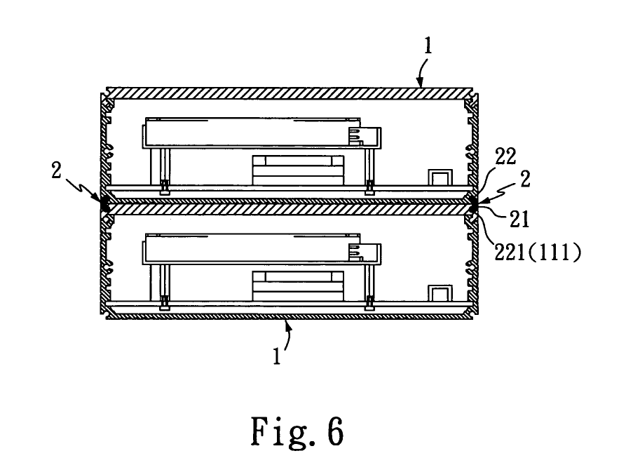

Alternatively, two microcomputer cases 1 of the present invention may be vertically coupled together as shown in FIG. 6. To do this, the two cases 1 are stacked with the slide channels 11 correspondingly located at two vertically adjoining sides of the two cases 1 in close contact with one another. Then, engage one coupling unit 2 with each pair of two adjoining slide channels 11 with the round-sectioned projections 221 on the insertion ribs 22 of the coupling unit 2 slidably fitted in the concave-sectioned recesses 111 in the slide channels 11. In this manner, the two cases 1 are firmly vertically coupled together.

With the above arrangements, two or more microcomputer cases may be firmly horizontally or vertically coupled together by engaging the coupling units 2 with every pair of two adjoining sliding channels 11 on the cases 1. Therefore, the coupling structure for microcomputer cases of the present invention is improved and practical for use.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A coupling structure for microcomputer cases, comprising:
at least two microcomputer cases, each of which being provided along longitudinal outer corners with a slide channel each; and
at least two coupling units being disposed between two of the cases that have been juxtaposed or stacked;
each of the coupling units including a longitudinally extended body portion having a predetermined width and two insertion ribs separately extended along and from two longitudinal sides of the body portion; and
the insertion ribs being configured corresponding to the slide channels on the cases so as to be slidably fitted in the slide channels.

2. The coupling structure for microcomputer cases as claimed in claim 1, wherein a motherboard is installed in each of the cases, and two end panels are separately fixed to front and rear open ends of the cases.

3. The coupling structure for microcomputer cases as claimed in claim 1, wherein each of the slide channels has a bottom formed into a concave-sectioned recess.

4. The coupling structure for microcomputer cases as claimed in claim 1, wherein the insertion ribs each have a free edge formed into a round-sectioned projection corresponding to the concave-sectioned recesses in the slide channels.

5. The coupling structure for microcomputer cases as claimed in claim 1, wherein each of the microcomputer cases has four longitudinal outer corners, and the slide channel is formed along each of the four longitudinal outer corners.
